(19) United States
(12) Patent Application Publication
(10) Pub. No.: US 2015/0103586 A1
(43) Pub. Date: Apr. 16, 2015

(54) WRITE DRIVER AND PROGRAM DRIVER FOR OTP (ONE-TIME PROGRAMMABLE) MEMORY WITH MAGNETIC TUNNELING JUNCTION CELLS

(71) Applicant: QUALCOMM Incorporated, San Diego, CA (US)

(72) Inventors: Sungryul KIM, San Diego, CA (US); Taehyun KIM, San Diego, CA (US); Jung Pill KIM, San Diego, CA (US)

(73) Assignee: QUALCOMM Incorporated, San Diego, CA (US)

(21) Appl. No.: 14/055,385

(22) Filed: Oct. 16, 2013

(51) Int. Cl. G11C 11/16

(52) U.S. Cl. CPC G11C 11/1673
USPC 365/158

(57) ABSTRACT

A one-time programmable (OTP) memory having a plurality of cells, each cell having a magnetic tunnel junction (MTJ) device; and the OTP memory further including a write driver to drive each MTJ device to an anti-parallel state, and a program driver to drive a subset of the MTJ devices to a blown state depending upon the information to be stored.

### FIELD OF DISCLOSURE

Embodiments of the present invention relate to one-time programmable memories with magnetic tunneling junction devices.

### BACKGROUND

A class of one-time programmable memory utilizes magnetic tunneling junction devices, where there is one magnetic tunneling junction device corresponding to each stored bit. The state of a tunneling junction device encodes the corresponding stored bit. The resistance of a tunneling junction device depends upon its state. A read operation reads a stored bit by determining the resistance of the corresponding tunneling junction device, where for example such a determination may be based upon a sensed voltage or current that is a function of the resistance. In practice, there should be sufficient margin in a read operation to mitigate read errors.

### SUMMARY

Embodiments of the invention are directed to systems and methods for a write driver and program driver for a one-time programmable memory with magnetic tunneling junction devices.

In an embodiment, an apparatus, such as an integrated circuit, includes a memory, a write driver, and a plurality of program drivers. The memory comprises a plurality of cells, each cell in the plurality of cells comprising a magnetic tunnel junction (MTJ) device. The write driver is coupled to the plurality of cells to drive each MTJ device in a subset of the plurality of cells to an anti-parallel state. The plurality of program drivers drive a subset of the MTJ devices to a blown state only if a first type of information bit is to be stored.

In another embodiment, a non-transitory, computer readable storage medium has stored instructions. The stored instructions when executed by at least one processor cause a computer system to perform a method comprising: driving each magnetic tunnel junction (MTJ) device in a subset of a plurality of cells to an anti-parallel state; and driving a subset of the MTJ devices to a blown state only if a first type of information bit is to be stored.

Another embodiment is a method comprising: driving each magnetic tunnel junction (MTJ) device in a subset of a plurality of cells to an anti-parallel state; and driving a subset of the MTJ devices to a blown state only if a first type of information bit is to be stored.

In another embodiment, an apparatus, such as an integrated circuit, includes a memory, a means for writing MTJ devices, and a means for driving MTJ devices. The memory comprises a plurality of cells, each cell in the plurality of cells comprising a magnetic tunnel junction (MTJ) device. The means for writing the MTJ devices is coupled to the plurality of cells to drive each MTJ device in a subset of the plurality of cells to an anti-parallel state. The means for driving MTJ devices drive a subset of the MTJ devices to a blown state only if a first type of information bit is to be stored.

### BRIEF DESCRIPTION OF THE DRAWINGS

The accompanying drawings are presented to aid in the description of embodiments of the invention and are provided solely for illustration of the embodiments and not limitation thereof.

FIG. 1 is a memory cell circuit according to an embodiment, where the magnetic tunneling junction in the memory cell is in an anti-parallel state.

FIG. 2 is a memory cell circuit according to an embodiment, where the magnetic tunneling junction in the memory cell is in a blown state.

FIG. 3 illustrates a flow diagram according to an embodiment.

FIG. 4 illustrates a computer system and a one-time programmable memory according to an embodiment.

FIG. 5 illustrates a communication network in which embodiments may find application.

### DETAILED DESCRIPTION

Aspects of the invention are disclosed in the following description and related drawings directed to specific embodiments of the invention. Alternate embodiments may be devised without departing from the scope of the invention. Additionally, well-known elements of the invention will not be described in detail or will be omitted so as not to obscure the relevant details of the invention.

The term “embodiments of the invention” does not require that all embodiments of the invention include the discussed feature, advantage or mode of operation.

The terminology used herein is for the purpose of describing particular embodiments only and is not intended to be limiting of embodiments of the invention. As used herein, the singular forms “a”, “an” and “the” are intended to include the plural forms as well, unless the context clearly indicates otherwise. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Further, many embodiments are described in terms of sequences of actions to be performed by, for example, elements of a computing cell. It will be recognized that specific circuits (e.g., application specific integrated circuits (ASICs)), one or more processors executing program instructions, or a combination of both, may perform the various actions described herein. Additionally, the sequences of actions described herein can be considered to be embodied entirely within any form of computer readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

When an MTJ (Magnetic Tunneling Junction) device is blown (put into a blown state), its barrier layer is changed to where the resistance is very low. Embodiments make use of the property that for an MTJ device, the difference in resistance values when in an anti-parallel state and a blown state is relatively large when compared to the difference in resistance values when in a parallel state and a blown state, or when compared to the difference in resistance values when in an anti-parallel state and a parallel state.

To increase the read margin for OTP memories, embodiments put the MTJ devices into either a blown state or an anti-parallel state, where a stored information bit is a function of state. When an embodiment OTP memory is manufactured, initially each MTJ device may be put into an anti-parallel state. At a later time, perhaps at the foundry or in the field, various MTJ devices within the OTP memory are selectively blown. The stored information is then represented by whether an MTJ device is in an anti-parallel state or a blown state. A read operation makes use of the difference in resistance values for the different states. Because the resistance values for an MTJ device when in an anti-parallel state and when in a blown state are substantially different from each other, the read margin is improved.

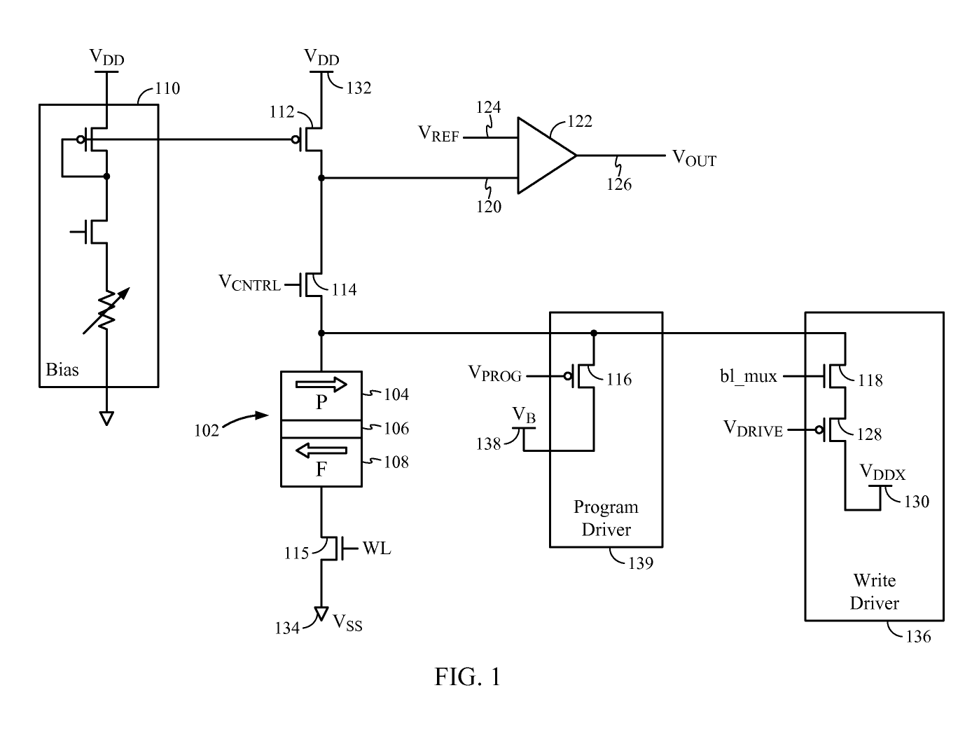

FIG. 1 is a memory cell circuit according to an embodiment, where an MTJ device 102 stores one bit of information. The MTJ device 102 comprises a pinned anti-ferromagnetic layer 104, a barrier layer 106, and a free anti-ferromagnetic layer 108. For ease of illustration, other layers for the MTJ device 102 are not shown, such as for example various conductive layers (electrodes) and a substrate. The layers of the MTJ device may comprise various types of materials, such as for example MgO for the barrier layer 106, PtMn for the free anti-ferromagnetic layer 108, and a CoFe/Ru/CoFeB system for the pinned anti-ferromagnetic layer 104. In FIG. 1, the arrows appearing inside the layers 104 and 108 indicate that the MTJ device 102 is in an anti-parallel state.

The bias circuit 110 provides a bias voltage to the gate of pMOSFET (p Metal Oxide Semiconductor Field Effect Transistor) 112. During a read operation, the transistors 114 and 115 are ON, and the transistors 116 and 118 are OFF. In the particular embodiment of FIG. 1, the transistors 114, 115, and 118 are nMOSFETs, and the transistor 116 is a pMOSFET. However, other embodiments may use other combinations of nMOSFETs and pMOSFETs, or other types of transistors, for these components.

During a read operation, the pMOSFET 112 is biased to provide a known current through the MTJ device 102, thereby providing a voltage at the input port 120 of the comparator 122. The comparator 122 compares the voltage at the input port 120 to a reference voltage V_{REF} provided at the input port 124. The reference voltage V_{REF} at the input port 124 is chosen so that the voltage at the output port 126 provides an indication of the state of the MTJ device 102, where the information bit stored in the MTJ device 102 is encoded by its state. For example, the anti-parallel state indicated in FIG. 1 may represent the “1” bit.

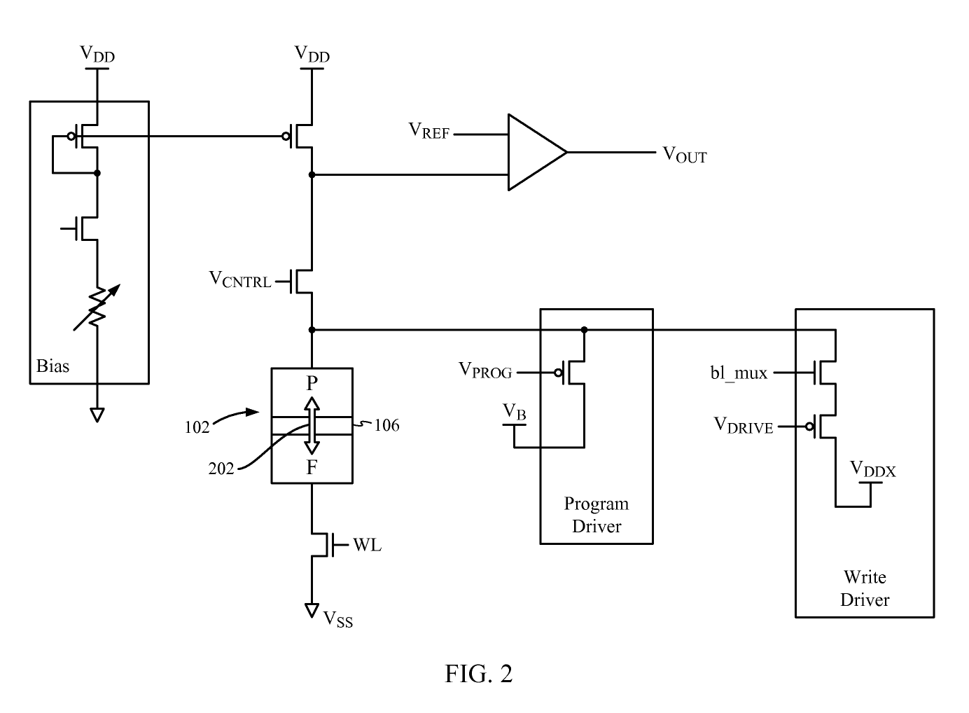

FIG. 2 is a memory circuit cell according to an embodiment, and is seen to be the same circuit as illustrated in FIG. 1 except that the MTJ device 102 is now in a blown state. The blown state is pictorially represented by the bidirectional arrow 202 to indicate that the barrier layer 106 is damaged so that the resistance of the MTJ device 102 is close to zero. If the anti-parallel state represents the “1” bit, then obviously the blown state represents the “0” bit. Of course, this particular designation for a stored bit merely serves as an example, and for other embodiments the anti-parallel state may represent the “0” bit, and the blown state may represent the “1” bit.

If R_{AP} denotes the resistance value when the MTJ device 102 is in an anti-parallel state, and R_{B} represents the resistance value when the MTJ device 102 is in a blown state, then during a read operation the voltages at the input port 102 to the comparator 122 are, respectively, I_{BIAS}*R_{AP} and I_{BIAS}*R_{B}, where I_{BIAS} is the bias current provided by the pMOSFET 112. The reference voltage V_{REF} provided to the input port 124 of comparator 122 may be set to the midpoint of these two voltages, where V_{REF}=(½)(I_{BIAS}*R_{AP}+I_{BIAS}*R_{B}). When the output voltage V_{OUT} at the output port 126 of the comparator 122 is HIGH, then the information bit read from the MTJ device 102 is interpreted as that bit associated with the anti-parallel state; and when the output voltage V_{OUT} is LOW, then the information bit read from the MTJ device 102 is interpreted as that bit associated with the blown state.

As discussed above, during a read operation, the transistors 114 and 115 are ON. The gate of the transistor 115 is labeled “WL” to indicate that the gate is tied to a word line. When the MTJ device 102 is to be programmed, the transistors 114 and 115 are turned OFF. The voltage at the gate of the transistor 114 is labeled as “V_{CNTRL}” to indicate that the voltage is a control voltage that is to be set LOW during programming of the MTJ device 102.

Before the OTP memory is programmed, each MTJ device is put into the anti-parallel state. For this operation, the transistors 114 and 116 are OFF, and the transistor 115 is ON. For ease of illustration, the transistors 118 and 128 are grouped together into a write driver 136. The transistor 118 is ON to select the MTJ device. For some embodiments, the transistor 128 may be shared among a subset of the MTJ devices within an OTP memory. A subset may not necessarily be a proper subset, for example, the subset may include the entire plurality of MTJ devices. The gate voltage of the transistor 118 is denoted in FIG. 1 as “bl_mux” to denote that a multiplexer may be utilized to turn on the transistor 118. For some embodiments, there is a plurality of transistors with the functionality of the transistor 118, each in one-to-tone correspondence with a MTJ device in the plurality of MTJ devices.

The gate voltage for the transistor 128, denoted by “V_{DRIVE}”, is set HIGH to turn ON the transistor 128, thereby driving the potential difference across the MTJ device 102 to the voltage V_{DDX} on the rail 130. The voltage V_{DDX} is chosen sufficiently high to put the MTJ device 102 into the anti-parallel state. Note that the voltage V_{DDX} of the rail 130 may be different from the voltage V_{DD} on the rail 132. These voltages are referenced to ground or substrate, represented by the voltage V_{SS} on the ground rail 134.

Once the MTJ devices are put into the anti-parallel state, the write driver 136 is deactivated, and various MTJ devices are selectively blown according to the information bits to be stored. For example, if the MTJ device illustrated in FIG. 1 is to be put into a blown state, then the gate voltage V_{PROG} is driven HIGH to turn ON transistor 116 so that the voltage V_{B} on the rail 138 is provided across the MTJ device 102. The voltage V_{B} is chosen large enough so that the MTJ 102 is put into a blown state, and in practice, the voltages V_{DDX} and V_{DD} are less than the voltage V_{B}. During this phase of programming, the transistor 114 is OFF and the transistor 115 is ON. The transistor 116 and its associated control signal V_{PROG} may be grouped together into a functional unit 139, termed a program driver. For some embodiments, there is a plurality of transistors similar in functionality to the transistor 116, in one-to-one correspondence with the plurality of MTJ devices.

For some embodiments, not all of the MTJ devices within a OTP memory need be put into an anti-parallel state before a subset of the MTJ devices are blown according to the information bits to be stored. For example, the MTJ devices that are to be put into a blown state may initially be in either the parallel state or the anti-parallel state.

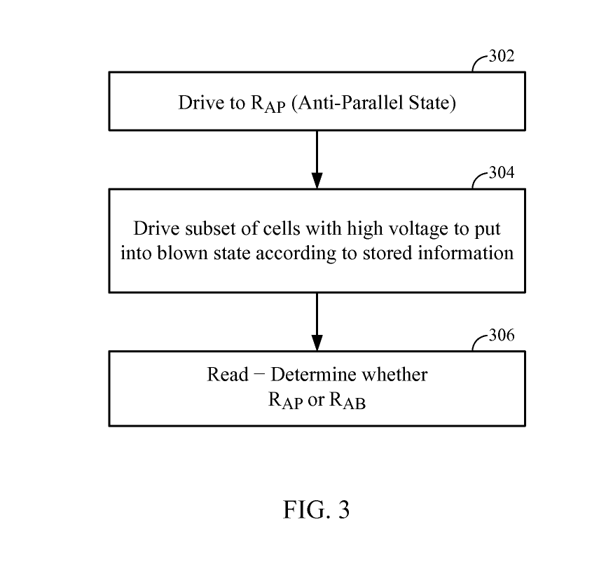

FIG. 3 illustrates a flow diagram according to the above-described embodiments. In step 302, MTJ devices are driven with a voltage so as to be put into the anti-parallel state to exhibit the resistance R_{AP}. For some embodiments, all MTJ devices within an OTP memory may be put into the anti-parallel state. In step 304, a subset of the MTJ devices are driven with a sufficiently high voltage so as to be put into the blown state according to the information bits to be stored. This high voltage is higher than the voltage provided in step 304. In step 306, the bit stored in an MTJ device is read by determining whether the resistance is closer to R_{AP}, the resistance when in the anti-parallel state, or R_{B}, the resistance when in the blown state.

An advantage of an embodiment is that a read operation does not disturb an MTJ device. That is, when an MTJ device is read, because it is either in the anti-parallel state or the blown state, the read operation does not affect the state (provided the read operation voltage is not high enough to cause an MTJ device in the anti-parallel state to be put into the blown state.) This is to be contrasted with an OTP memory in which an MTJ device is programmed into either the anti-parallel state or the parallel state, in which case a read operation on an MTJ device in the parallel state may disturb the MTJ device and put it into the anti-parallel state.

For some embodiments, the anti-parallel programming phase of the MTJ devices in an OTP memory may be performed at the point of manufacture or packaging of the OTP memory; and the programming phase in which a subset of the MTJ devices are put into the blown state so that the arrangement of anti-parallel and blown MTJ devices represent the stored bits may be performed at the point of manufacture or packaging, or in the field, after the step of programming into the anti-parallel state.

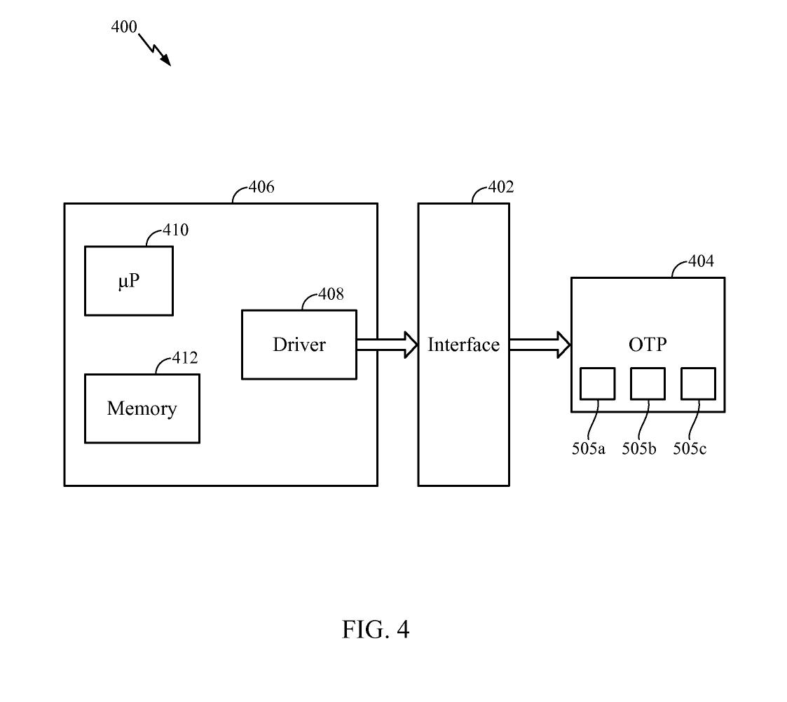

A computer system may be used to perform one or both programming phases by driving the appropriate signals to the OTP. A system (apparatus) 400 for programming an OTP 404 is illustrated in FIG. 4, where the interface 402 represents the signals for programming the OTP memory 404. The OTP memory 404 comprises a plurality of cells, where for ease of illustration only three are shown and labeled 505a, 505b, and 505c. The computer system 406 includes a driver 408 for providing the appropriate signals as described previously for the write driver 136 and the voltage V_{PROG} to the gate of the transistor 116. The computer system 406 includes a processor 410, which may represent multiple processors, and a system memory 412, which may represent a memory hierarchy. The system memory 412 may be referred to as a non-transitory, computer readable storage medium in which instructions are stored. The instructions, when executed by the computer system 406, perform some or all of the steps as discussed previously for the two phases of programming: one phase to program the MTJ devices in the anti-parallel state, and the other phase to put a subset of the MTJ devices in the blown state.

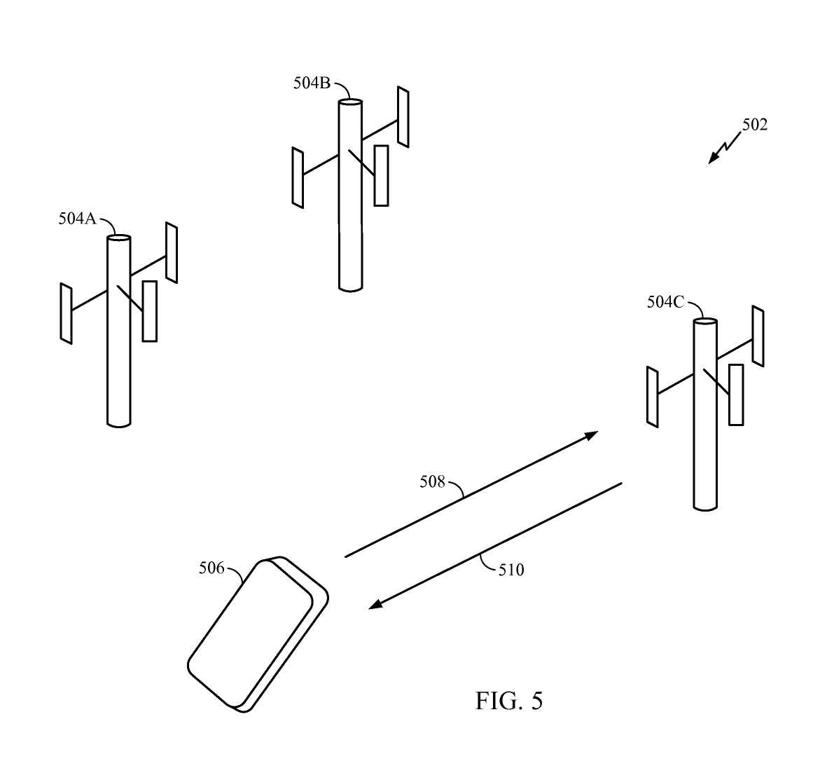

Embodiments described above may find application in a number of devices, either used in a stand-alone mode or as part of a network. For example, FIG. 5 illustrates a wireless communication system in which embodiments may find application. FIG. 5 illustrates a wireless communication network 502 comprising base stations 504A, 504B, and 504C. FIG. 5 shows a communication device, labeled 506, which may be a mobile cellular communication device such as a cellular phone, a tablet, or some other kind of communication device suitable for a cellular phone network, such as a computer or computer system. The communication device 506 need not be mobile. In the particular example of FIG. 5, the communication device 506 is located within the cell associated with the base station 504C. Arrows 508 and 510 pictorially represent the uplink channel and the downlink channel, respectively, by which the communication device 506 communicates with the base station 504C.

Embodiments may be used in data processing systems associated with the communication device 506, or with the base station 504C, or both, for example. FIG. 5 illustrates only one application among many in which the embodiments described herein may be employed.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

Accordingly, an embodiment of the invention can include a non-transitory, computer readable storage medium embodying a method for programming an OTP (One-Time Programmable) memory with MTJ (Magnetic Tunneling Junction) devices. Accordingly, the invention is not limited to illustrated examples and any means for performing the functionality described herein are included in embodiments of the invention.

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order. Furthermore, although elements of the invention may be described or claimed in the singular, the plural is contemplated unless limitation to the singular is explicitly stated.

What is claimed is:

1. An apparatus comprising:
a memory comprising a plurality of cells, each cell in the plurality of cells comprising a magnetic tunnel junction (MTJ) device;
a write driver coupled to the plurality of cells to drive each MTJ device in a subset of the plurality of cells to an anti-parallel state; and
a plurality of program drivers to drive a subset of the MTJ devices to a blown state only if a first type of information bit is to be stored.

2. The apparatus of claim 1, wherein the subset of the plurality of cells includes each cell in the plurality of cells.

3. The apparatus of claim 1, further comprising:
a first rail at a first voltage; and
a second rail at a second voltage less than the first voltage;
each program driver comprising a transistor to couple the first rail to a corresponding MTJ device when the transistor is ON; and
the write driver comprising at least one transistor to couple each MTJ device in the subset of the plurality of cells to the second rail when the at least one transistor is ON.

4. The apparatus of claim 3, wherein the subset of the plurality of cells includes each cell in the plurality of cells.

5. The apparatus of claim 4, further comprising a one-time programmable (OTP) memory, wherein the OTP memory includes the plurality of cells.

6. The apparatus of claim 1, wherein the memory is a one-time programmable (OTP) memory, wherein the OTP memory includes the plurality of cells.

7. The apparatus of claim 1, wherein the apparatus is used in a device selected from the group consisting of a computer, a cellular phone, a tablet, and a base station.

8. The apparatus of claim 1, further comprising:
a computer system comprising a system memory and at least one processor, the system memory having stored instructions that when executed by the at least one processor cause the computer system to perform a method comprising controlling the write driver to drive each MTJ device in a subset of the plurality of cells to the anti-parallel state.

9. The apparatus of claim 8, the method further comprising controlling the plurality of program drivers to drive a subset of the MTJ devices to the blown state only if a first type of information bit is to be stored.

10. The apparatus of claim 9, wherein the step of controlling the plurality of program drivers to drive a subset of the MTJ devices to a blown state only if a first type of information bit is to be stored is performed only after the write driver drives each MTJ device in a subset of the plurality of cells to the anti-parallel state.

11. The apparatus of claim 10, wherein the subset of the plurality of cells includes each cell in the plurality of cells.

12. A non-transitory, computer readable storage medium having stored instructions, the stored instructions when executed by at least one processor cause a computer system to perform a method comprising:
driving each magnetic tunnel junction (MTJ) device in a subset of a plurality of cells to an anti-parallel state; and
driving a subset of the MTJ devices to a blown state only if a first type of information bit is to be stored.

13. The non-transitory, computer readable storage medium of claim 12, wherein the subset of the plurality of cells includes each cell in the plurality of cells.

14. The non-transitory, computer readable storage medium of claim 12, wherein the plurality of cells are part of a one-time programmable (OTP) memory.

15. The non-transitory, computer readable storage medium of claim 12, wherein the step of driving the subset of the MTJ devices to the blown state only if a first type of information bit is to be stored is performed after the step of driving each magnetic tunnel junction (MTJ) device in the subset of a plurality of cells to the anti-parallel state.

16. A method comprising:
driving each magnetic tunnel junction (MTJ) device in a subset of a plurality of cells to an anti-parallel state; and
driving a subset of the MTJ devices to a blown state only if a first type of information bit is to be stored.

17. The method of claim 16, wherein the subset of the plurality of cells includes each cell in the plurality of cells.

18. The method of claim 16, wherein the plurality of cells are part of a one-time programmable (OTP) memory.

19. The method of claim 16, wherein the step of driving the subset of the MTJ devices to the blown state only if a first type of information bit is to be stored is performed after the step of driving each magnetic tunnel junction (MTJ) device in the subset of a plurality of cells to the anti-parallel state.

20. An apparatus comprising:
a memory comprising a plurality of cells, each cell in the plurality of cells comprising a magnetic tunnel junction (MTJ) device;
a means for writing MTJ devices, the means for writing the MTJ devices coupled to the plurality of cells to drive each MTJ device in a subset of the plurality of cells to an anti-parallel state; and
a means for driving MTJ devices, the means for driving MTJ devices to drive a subset of the MTJ devices to a blown state only if a first type of information bit is to be stored.
